(19) United States
(12) Patent Application Publication
(10) Pub. No.: US 2007/0006802 A1
(43) Pub. Date: Jan. 11, 2007

(54) N-TYPE BULK SINGLE CRYSTAL ZINC OXIDE

(76) Inventors: Jeffrey E. Nause, Mableton, GA (US); William Michael Nemeth, Atlanta, GA (US)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 11/428,284

(22) Filed: Jun. 30, 2006

Related U.S. Application Data
(60) Provisional application No. 60/697,223, filed on Jul. 6, 2005.

(51) Int. Cl. C30B 23/00; C30B 25/00; C30B 28/12; C30B 28/14

(52) U.S. Cl. 117/108

(57) ABSTRACT

A ZnO bulk single crystal of the invention has n-type conductivity with a maximum resistivity of one (1) ohm-centimeter (Ω-cm). N-type conductivity is achieved through introduction of dopants in the formation of the crystal using a Bridgeman growth technique. The dopants can be a single species or combination of species from Group III, Group VII, Lanthanides, Actinides, Transition metals, or other element or combination of elements resulting in a net positive addition of carriers, i.e. free electrons, to the crystal. Dopant concentration ranges from 1×10¹⁵ to 5×10^{21 atoms}/cc. The maximum resistivity at which doped ZnO will exhibit enhanced n-type behavior is one (1) Ω-cm at room temperature, so dopant concentrations used to form the crystal are present in an amount that yields this result. The conductivity of the ZnO crystal can be tailored due to the general trend of increasing dopant concentration providing increasing conductivity. The crystal can be cut and polished to produce one or more wafers.

### CROSS-REFERENCE TO RELATED APPLICATIONS

This application claims the benefit of U.S. Provisional Application No. 60/697,223 filed Jul. 6, 2005 entitled “N-Type Bulk Single Crystal Zinc Oxide,” which is incorporated by reference herein in its entirety.

### FIELD OF THE INVENTION

This invention relates to n-type zinc oxide (ZnO) single crystals. Such crystals can be used as substrates upon which can be formed electronic, electro-optic, or opto-electronic devices or circuits comprising one or more of these devices.

### BACKGROUND OF THE INVENTION

As electronic and optoelectronic devices evolve into more sophisticated designs and arrangements, it is believed that an effective transparent conducting oxide will, in some cases, yield better device performance than existing technology. Zinc oxide (ZnO) has been rediscovered as a material of interest due to its beneficial semiconducting properties. It has a wide band gap (3.37 eV) and a high exciton binding energy (60 meV). Furthermore, since ZnO has a low lattice mismatch (˜2%) with GaN, it serves as a good substrate candidate for nitride devices. ZnO is inherently n-type due to defects such as zinc interstitials and oxygen vacancies; however, additional dopants can be added to pronounce even higher electrical conductivity.

Some research has been accomplished in an effort to produce extrinsically n-type ZnO. The following table (Table 1) lists some efforts used to incorporate possible n-type dopants into various manifestations of ZnO.

TABLE 1
Comparison of various dopants in ZnO

| ZnO | Method of | | Resistivity | Mobility | Carriers | |
|---|---|---|---|---|---|---|
| Description | Formation | Dopant(s) | (Ω cm) | (cm²/Vs) | (/cm³) | Ref. |
| Thin Film | MOCVD | B, Al | ˜0.01 | ˜100 | ˜10²¹ | Pat. 5545443 |
| Thin Film | N/A | B, Sc, Y, La, | <10 | | | Pat. 6606333 |
| | | Ac, Tl, V, | | | | |
| | | Nb, Ta, P, | | | | |
| | | As, Sb Bi | | | | |
| Thin Film | MOCVD | Al, Ga | 0.1 to 0.002 | 31.00 | 5.9 × 10¹⁹ | Haga |
| Thin Film | MOCVD | Ga | 2.6 × 10⁻⁴ | | 4.0 × 10²¹ | Li |
| Thin Film | Ion Beam | Al | 2.5 × 10⁻³ | 14.70 | 1.7 × 10²⁰ | Tsurumi |
| | Sputtering | | | | | |
| Thin Film | PLD | Al | 2.2 × 10⁻⁴ | 32.00 | 8.8 × 10²⁰ | Kim |
| Thin Film | PLD | Al, Ga | 0.00050 | ˜60 | 1.0 × 10²⁰ | Lorenz |
| Thin film | PLD | Al | 1 | | 5.0 × 10¹⁸ | Ryu |
| Bulk | Hydrothermal | Zn | 1-100 | | | Pat. 5393444 |
| Bulk | Hydrothermal | Al diffused | 10³ | 95.00 | | Pat. 5393444 |
| Bulk | Hydrothermal | Al, Ga, In, | | | | Pat. 6841000 |
| | | Fe, Ni, Mn, | | | | |
| | | Co, Cr | | | | |
| Bulk | Hydrothermal | Ga, In, Fe | | | | Demianets |
| | | Mn, Co, Sc, F | | | | |
| Bulk | Flux | Al | | | ˜10¹⁸ | Ohashi |

It should be noted that the applicant's claims detail in situ doping in bulk form, so dopant uniformity is relatively constant through the thickness of the substrate, especially when compared to diffusion and implantation techniques. It is of interest that hydrothermal bulk growth techniques typically include an alkaline mineralizer containing one or a combination of the acceptor dopants: Li, Na, or K. These impurities incorporate into the lattice and greatly increase the electrical resistivity, so n-type doping is very difficult. It is also of interest to note a hydrothermal technique that does not use an alkaline mineralizer (U.S. Pat. No. 5,393,444), still yields a minimum resistivity of 1 Ω-cm.

### BRIEF SUMMARY OF THE INVENTION

An article of manufacture in accordance with an embodiment of the invention comprises a bulk zinc-oxide (ZnO) single crystal containing one or more dopants that enhance its n-type conductivity to a maximum resistivity of one (1) ohm-centimeter (Ω-cm). The dopants can comprise a single species or combination of species from Group III, Group VII, Lanthanides, Actinides, Transition metals, or other element or combination of elements resulting in a net positive addition of carriers, i.e. free electrons, to the crystal. Dopant elements that are electron contributors can be added to hole contributors (for example, Li, Na, K, N) to produce n-type ZnO, so long as the number of electrons added is greater than the number of holes for a net addition of carrier electrons (for example, 1×10^{16 atoms}/cc Fe and 1×10^{15 atoms}/cc Na atoms will yield n-type ZnO). The dopants can be present in a concentration ranging from 1×10^{15 atoms}/cc to 5×10^{21 atoms}/cc. The zinc-oxide (ZnO) single crystal can be cut and polished into one or more wafers.

A method in accordance with an embodiment of the invention comprises the step of forming a n-type bulk zinc oxide (ZnO) single crystal with a maximum resistivity of 1 Ω-cm using a modified Bridgeman growth technique in which the ZnO single crystal is formed from a ZnO melt contained within a solid-phase ZnO shell in the presence of one or more dopants to increase the crystal's n-type conductivity. A gas overpressure can be used in the growth technique to prevent decomposition of the ZnO. The dopants can be a single or different species from Group III, Group VII, Lanthanides, Actinides, Transition metals, or any other element or combination of elements resulting in a net positive addition of carriers to the crystal. The dopants can be present in a concentration ranging from 1×10^{15 atoms}/cc to 5×10^{21 atoms}/cc. The method can further comprise the steps of cutting and processing the ZnO single crystal into polished substrates.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a diagram of the modified Bridgman growth apparatus.

### DETAILED DESCRIPTION OF THE INVENTION

The present invention now will be described more fully hereinafter with reference to the accompanying drawings, in which some, but not all embodiments of the inventions are shown. These inventions may be embodied in many different forms and should not be construed as limited to the embodiments set forth herein; rather, these embodiments are provided so that this disclosure will satisfy applicable legal requirements. Like numbers refer to like elements throughout.

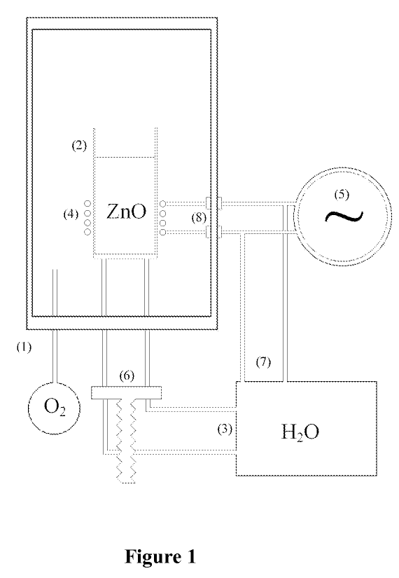

The crystal growth apparatus, seen in FIG. 1, utilizes a modified Bridgeman growth technique including a pressure vessel that contains pressurized gas (1), such as inert gases, N₂O, O₂, or other oxide gases. The apparatus also includes a cooling unit (2) that is situated in the pressure vessel. The cooling unit receives a coolant flow from outside of the vessel (3) and has cooled surfaces that define an enclosure, which receives the ZnO with proper dopant concentration (1×10¹⁵-5×10^{21 atoms}/cc). The following table (Table 2) lists some electrical characterization results from doped, melt grown ZnO.

TABLE 2
Results of Cermet melt grown doped ZnO single crystals

| | Resistivity | | |
|---|---|---|---|
| Dopant | (Ω cm) | Mobility (cm²/Vs) | Carriers (/cm³) |
| In | 1.70 × 10⁻² | 106 | 3.5 × 10¹⁸ |
| In | 3.50 × 10⁻² | 100 | 1.8 × 10¹⁸ |
| Ga | 6.60 × 10⁻³ | 74 | 1.3 × 10¹⁹ |
| B | 2.00 × 10⁻¹ | 245 | 1.2 × 10¹⁷ |
| Al | 2.20 × 10⁻² | 113 | 2.5 × 10¹⁸ |
| In | 6.50 × 10⁻² | 130 | 7.0 × 10¹⁷ |
| Ga | 1.60 × 10⁻² | 65 | 6.0 × 10¹⁸ |
| Gd | 2.10 × 10⁻² | 99 | 2.9 × 10¹⁸ |
| Er + Li | 1.00 × 10⁻² | 98 | 6.0 × 10¹⁸ |
| Ce + Li | 1.30 × 10⁻² | 134 | 3.6 × 10¹⁸ |
| Er + Tm | 2.00 × 10⁻² | 95 | 3.2 × 10¹⁸ |

The apparatus further includes an inductive heating element (4) situated in the vessel, which is coupled to receive radio-frequency (rf) power externally to the vessel (5). The element heats the interior portion of the doped ZnO to form a molten interior portion contained by a relatively cool, exterior solid-phase portion of the doped ZnO that is closer relative to the molten interior, to the cooled surfaces of the cooling unit. Due to the pressure exerted by the gas contained in the vessel, the liquid interior of the doped ZnO becomes congruently melting to prevent its decomposition. The cooling unit is then lowered (6) through the element to produce crystal nucleation at the base of the cooling unit and preferential crystal growth through the distance traveled.

In addition to rf power, the heating element receives a coolant flow (7) from a feedthrough that extends through a wall of the pressure vessel. In proximity to the vessel wall, the feedthrough has two coaxial conductors (8) to improve the electric power transfer to the heating element and to reduce heating of the external surfaces of the vessel. The two conductors of the feedthrough are cylindrical in shape, and define two channels for channeling a coolant flow to and from, respectively, the heating element.

### EXAMPLE 1

A precursor which will yield 10¹⁹ Ga^{carriers}/cc is added to the ZnO precursor before crystal growth in the cooling unit (2). The charge is melted and crystals are directionally solidified as described. The resulting crystals are processed into polished substrates.

### EXAMPLE 2

A precursor which will yield 10¹⁹ Er^{caries}/cc is added to the ZnO precursor before crystal growth in the cooling unit (2). The charge is melted and crystals are directionally solidified as described. The resulting crystals are processed into polished substrates.

### EXAMPLE 3

Precursors which will yield 10¹⁹ Ga^{caries}/cc and 10¹⁹ Al^{caries}/cc are added to the ZnO precursor before crystal growth in the cooling unit (2). The charge is melted and crystals are directionally solidified as described. The resulting crystals are processed into polished substrates.

### EXAMPLE 4

Precursors which will yield 10¹⁹ Er^{caries}/cc and 10¹⁹ Tm^{caries}/cc are added to the ZnO precursor before crystal growth in the cooling unit (2). The charge is melted and crystals are directionally solidified as described. The resulting crystals are processed into polished substrates.

### EXAMPLE 5

Precursors which will yield 10¹⁹ In^{caries}/cc and 10¹⁹ Tm^{caries}/cc are added to the ZnO precursor before crystal growth in the cooling unit (2). The charge is melted and crystals are directionally solidified as described. The resulting crystals are processed into polished substrates.

### EXAMPLE 6

Precursors which will yield 10¹⁹ Er^{caries}/cc and 10¹⁸ Li^{caries}/cc are added to the ZnO precursor before crystal growth in the cooling unit (2). The charge is melted and crystals are directionally solidified as described. The resulting crystals are processed into polished substrates.

### EXAMPLE 7

Precursors which will yield 10¹⁹ Ga^{caries}/cc, 10¹⁸ Ga^{caries}/cc, 10¹⁸ Na^{caries}/cc, and 10¹⁸ Li^{caries}/cc are added to the ZnO precursor before crystal growth in the cooling unit (2). The charge is melted and crystals are directionally solidified as described. The resulting crystals are processed into polished substrates.

To one skilled in the art, it should be immediately obvious that there exist innumerable combinations that can be utilized to achieve the net positive addition of carriers to a ZnO single crystal using a variety of dopant impurities. The specified embodiments serve as descriptions of possibilities but do not limit the scope of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. An article of manufacture comprising:
a bulk zinc-oxide (ZnO) single crystal containing one or more dopants that enhance its n-type conductivity to a maximum resistivity of 1 Ω-cm.

2. The article of claim 1 wherein the one or more dopants comprise a single species or combination of species from Group III, Group VII, Lanthanides, Actinides, Transition metals, or other element or combination of elements resulting in a net positive addition of electron carriers to the crystal.

3. The article of claim 1 wherein the dopants comprise a single atomic species.

4. The article of claim 3 wherein the dopants comprise Group III elements.

5. The article of claim 3 wherein the dopants comprise Group VII elements.

6. The article of claim 3 wherein the dopants comprise Lanthanide elements.

7. The article of claim 3 wherein the dopants comprise Actinide elements.

8. The article of claim 3 wherein the dopants comprise Transition metals.

9. The article of claim 1 wherein the dopants range in atomic concentration from 1×10^{15 atoms}/cc to 5×10^{21 atoms}/cc

10. The article of claim 1 wherein the dopants comprise different dopant species.

11. The article of claim 10 wherein the dopants comprise a combination of two or more of Group III, Group VII, Lanthanides, Actinides, and Transition metals.

12. The article of claim 10 wherein the dopants include at least one element contributing holes and at least one element contributing electrons with a net positive addition of electrons.

13. The article of claim 1 wherein the ZnO single crystal has a wafer form.

14. A method comprising the step of:
forming a n-type bulk zinc oxide (ZnO) single crystal with a maximum resistivity of 1 Ω-cm using a modified Bridgeman growth technique in which the ZnO single crystal is formed from a ZnO melt contained within a solid-phase ZnO shell in the presence of one or more dopants to increase the crystal's n-type conductivity.

15. The method of claim 14 wherein the one or more dopants comprise a single species or combination of species from Group III, Group VII, Lanthanides, Actinides, Transition metals, or other element or combination of elements resulting in a net positive addition of electron carriers to the crystal.

16. The method of claim 14 wherein the ZnO single crystal is formed in the presence of a single species of dopant.

17. The method of claim 16 wherein the dopants comprise Group III elements.

18. The method of claim 16 wherein the dopants comprise Group VII elements.

19. The method of claim 16 wherein the dopants comprise Lanthanide elements.

20. The method of claim 16 wherein the dopants comprise Actinide elements.

21. The method of claim 16 wherein the dopants comprise Transition metals.

22. The method of claim 14 wherein the ZnO single crystal is formed so that the dopant is present in an atomic concentration ranging from 1×10^{15 atoms}/cc to 5×10^{21 atoms}/cc.

23. The method of claim 14 wherein the dopants comprise different dopant species.

24. The method of claim 23 wherein the dopants comprise a combination of two or more of Group III, Group VII, Lanthanides, Actinides, and Transition metals.

25. The article of claim 24 wherein the dopants include at least one element contributing holes and at least one element contributing electrons with a net positive addition of electrons.

26. The method of claim 14 further comprising the steps of cutting and processing the ZnO single crystal into polished substrates.

27. A method of manufacturing comprising the step of:
forming a n-type bulk ZnO single crystal with a maximum resistivity of 1 Ω-cm using a modified Bridgeman growth technique in which a melt of ZnO is formed with a heating element and is contained within a solid phase portion of ZnO cooled by a cooling unit and in which the ZnO is pressurized with gas from a source and in which one or more dopants are introduced to increase the ZnO crystal's n-type conductivity, to form the n-type ZnO single crystal.
